(19) United States
(12) Patent Application Publication
(10) Pub. No.: US 2026/0252186 A1
(43) Pub. Date: Aug. 27, 2026

(54) TOUCH DISPLAY PANEL AND TOUCH DISPLAY APPARATUS

(71) Applicants: Ordos Yuansheng Optoelectronics Co., Ltd., Ordos, Inner Mongolia (CN); BOE Technology Group Co., Ltd., Beijing (CN)

(72) Inventors: Zhen SHI, Beijing (CN); Guodong WANG, Beijing (CN); Fengguo WANG, Beijing (CN); Shoubo SUN, Beijing (CN); Yongsheng LI, Beijing (CN); Bo WANG, Beijing (CN); Guojiang YU, Beijing (CN); Shilong ZHANG, Beijing (CN); Wei MIAO, Beijing (CN); Yongfei REN, Beijing (CN); Yuanhang YANG, Beijing (CN)

(21) Appl. No.: 19/160,354

(22) PCT Filed: Aug. 12, 2024
(86) PCT No.: PCT/CN2024/111510

§ 371 Date: Aug. 27, 2025

(30) Foreign Application Priority Data
Sep. 18, 2023 (CN) 202311203946.3

(51) Int. Cl. G06F 3/041; H10D 86/40

(52) U.S. Cl. CPC G06F 3/0412; G06F 3/0416; H10D 86/441

(57) ABSTRACT

A touch display panel and a touch display apparatus. The touch display panel includes: a base substrate; a first electrode layer, on a side of the base substrate, where the first electrode layer includes: first signal lines extending in a first direction, and electrode portions connected to the first signal lines; a touch control layer, on the side of the base substrate as the first electrode layer; a first insulating layer, between the first electrode layer and the touch control layer; pixel electrodes, on the same side of the base substrate as the first electrode layer; where orthographic projections of the electrode portions on the base substrate are only located at orthographic projections of gaps between some adjacent pixel electrodes of the pixel electrodes on the base substrate.

### CROSS-REFERENCE OF RELATED APPLICATIONS

The present application a national phase entry under 35 U.S. C § 371 of International Application No. PCT/CN2024/111510, filed on Aug. 12, 2024, which claims the priority from Chinese Patent Application No. 202311203946.3, filed with the China National Intellectual Property Administration on Sep. 18, 2023 and entitled “Touch Display Panel and Touch Display Device”, which is hereby incorporated by reference in its entirety.

### TECHNICAL FIELD

The present disclosure relates to the field of semiconductor technology, and in particular to a touch display panel and a touch display device.

### BACKGROUND

Liquid Crystal Display (LCD) is the most widely used flat panel display at present, and has gradually become a display with high-resolution color screen used in various electronic devices such as mobile phones, personal digital assistants (PDAs), digital cameras, desktop computers or laptop computers.

With the development and progress of liquid crystal display technology, people have put forward higher requirements on LCD display quality, appearance design, human-machine interface, etc. Touch technology has become a hot spot in technological development due to its convenient operation and high integration. Touch technology has developed rapidly in recent years, and many types of touch panels have been put into mass production. According to the different locations of touch sensors, existing touch panels can be divided into touch sensors covered on a liquid crystal cell (On Cell), touch sensors embedded in a liquid crystal cell (In Cell), and touch sensors externally mounted on a display panel (Out Cell). Among them, In-Cell touch panel refers to a method of embedding the touch function into liquid crystal pixels, which not only further reduces the thickness of the whole machine, but also can be produced together with LCD without additional production processes, and does not affect its visibility in bright environments such as outdoors. Therefore, research on In-Cell touch panels is becoming increasingly popular.

### SUMMARY

The present disclosure provides a touch display panel and a touch display device. The touch display panel includes:
a base substrate;
a first electrode layer, on a side of the base substrate, where the first electrode layer includes: a plurality of first signal lines extending in a first direction, and a plurality of electrode portions connected to the plurality of first signal lines;
a touch control layer, on the side of the base substrate as the first electrode layer, where the touch control layer includes: a plurality of touch control electrodes spaced apart from each other;
a first insulating layer, between the first electrode layer and the touch control layer, where the first insulating layer is provided with a plurality of first via holes; at least some of the plurality of electrode portions are electrically connected to the touch control electrodes through the first via holes;
a plurality of pixel electrodes, on the same side of the base substrate as the first electrode layer;
where orthographic projections of the plurality of electrode portions on the base substrate are only located at orthographic projections of gaps between some adjacent pixel electrodes of the plurality of pixel electrodes on the base substrate.

In some embodiments, all of the electrode portions are electrically connected to the touch control electrodes through the first via holes.

In some embodiments, a minimum distance between orthographic projections of at least some adjacent electrode portions on the base substrate in the first direction is greater than a length of an orthographic projection of the pixel electrode on the base substrate in the first direction.

In some embodiments, a minimum distance between orthographic projections of at least some adjacent electrode portions on the base substrate in a second direction is greater than a length of an orthographic projection of the pixel electrode on the base substrate in the second direction, and the second direction is perpendicular to the first direction.

In some embodiments, the touch control layer includes: a plurality of touch control electrode groups extending in the first direction and arranged in the second direction;
the plurality of electrode portions include: a plurality of electrode portion groups extending in the first direction and arranged in the second direction, where an orthographic projection of the touch control electrode group on the base substrate at least partially overlaps with an orthographic projection of the electrode portion group on the base substrate;
at least one electrode portion group of the plurality of electrode portion groups includes: a plurality of sub-electrode portion groups arranged in the first direction, where the sub-electrode portion group includes: at least one electrode portion of the plurality of electrode portions; an orthographic projection of the touch control electrode on the base substrate at least partially overlaps with an orthographic projection of the sub-electrode portion group on the base substrate;
the sub-electrode portion groups in a same electrode portion group are arranged in a staggered manner.

In some embodiments, each of the electrode portions in a same sub-electrode portion group is located in a gap between adjacent columns of pixel electrodes.

In some embodiments, each of the electrode portions in a same sub-electrode portion group is electrically connected to a same first signal line.

In some embodiments, each of the electrode portions in a same region where the touch control electrode is located is located in a gap between adjacent columns of pixel electrodes.

In some embodiments, each of the electrode portions in a same region where the touch control electrode is located is electrically connected to a same first signal line.

In some embodiments, a spacing between two adjacent sub-electrode portion groups in the second direction is substantially equal to a width of the touch control electrode in the second direction.

In some embodiments, a spacing between one pair of two adjacent sub-electrode portion groups in the second direction is substantially equal to a spacing between another pair of two adjacent sub-electrode portion groups in the second direction.

In some embodiments, the electrode portion includes: a first-type electrode portion;
the touch display panel includes: an array substrate and an opposite substrate arranged opposite to each other;
where the opposite substrate is provided with a first spacer on a side facing the array substrate; the first spacer includes a first surface facing the array substrate;
an orthographic projection of at least some of the first-type electrode portions on the base substrate has an overlapping region with an orthographic projection of the first surface on the base substrate.

In some embodiments, an orthographic projection of the first via hole on the base substrate and the orthographic projection of the first surface on the base substrate do not overlap with each other.

In some embodiments, the electrode portion further includes: a second-type electrode portion;
an orthographic projection of the second-type electrode portion on the base substrate and the orthographic projection of the first surface on the base substrate do not overlap with each other.

In some embodiments, the electrode portion includes a first-type electrode portion and a second-type electrode portion; and
a length of the first-type electrode portion in the second direction is greater than a length of the second-type electrode portion in the second direction.

In some embodiments, the touch display panel further includes: a plurality of gate lines extending in a second direction; at least one gate line of the plurality of gate lines includes: a plurality of first sub-gate line portions sequentially arranged in the second direction; and adjacent first sub-gate line portions are disconnected;
the touch display panel further includes: a transfer portion arranged at a side of the electrode portion away from the first signal line; where an orthographic projection of the transfer portion on the base substrate and an orthographic projection of the first sub-gate line portion on the base substrate have an overlapping region;
the touch display panel further includes: a second insulating layer between the first electrode layer and the gate line, where the second insulating layer is provided with a second via hole; and the transfer portion is electrically connected to the first sub-gate line portion through the second via hole.

In some embodiments, the gate line further includes: a connection end connected to an end of the first sub-gate line portion; a width of the connection end in the first direction is greater than a width of the first sub-gate line portion in the first direction;
one end of the transfer portion is connected to a connection end of one first sub-gate line portion through one second via hole, and the other end of the transfer portion is connected to a connection end of another first sub-gate line portion through another second via hole, so that adjacent first sub-gate line portions are connected through the transfer portion.

In some embodiments, the gate line further includes: a second sub-gate line portion connected to the first sub-gate line portion;
a width of the second sub-gate line portion in the first direction is greater than a width of the first sub-gate line portion in the first direction; and
the width of the second sub-gate line portion in the first direction is substantially equal to a width of the connection end in the first direction.

In some embodiments, an orthographic projection of the second sub-gate line portion on the base substrate does not overlap with an orthographic projection of the electrode portion on the base substrate.

In some embodiments, the touch display panel further includes: a first electrode of a transistor; where the electrode portion includes a second-type electrode portion;
in a gap between at least some adjacent first signal lines, the orthographic projection of the transfer portion on the base substrate is located between an orthographic projection of the first electrode of the transistor on the base substrate and an orthographic projection of the second-type electrode portion on the base substrate.

In some embodiments, a length of the second-type electrode portion in the second direction is smaller than a length of the first electrode of the transistor in the second direction.

In some embodiments, a length of the first electrode of the transistor in the second direction is smaller than a length of the transfer portion in the first direction.

In some embodiments, the electrode portion includes: a first-type electrode portion;
a length of the first-type electrode portion in the second direction is greater than a length of the first electrode of the transistor in the second direction; and
the length of the first-type electrode portion in the second direction is less than a length of the transfer portion in the second direction.

In some embodiments, the touch display panel further includes: a plurality of data lines extending in the first direction and a first electrode of a transistor electrically connected to the pixel electrode;
one first signal line and one data line form a signal wiring group;
in a same signal wiring group, the electrode portion is electrically connected to a side of the first signal line away from the data line, and the first electrode of the transistor is arranged on a side of the data line away from the first signal line.

In some embodiments, an orthographic projection of an extension line of an outer edge of the electrode portion parallel to the second direction on the base substrate overlaps with an orthographic projection of the first electrode of the transistor on the base substrate.

In some embodiments, the first signal line and the data line are arranged in a same layer.

In some embodiments, the touch control layer is arranged between the first electrode layer and a layer where the pixel electrode is located;
the touch control electrode includes: a third via hole; where the pixel electrode is connected to the first electrode of the transistor through the third via hole.

In some embodiments, the touch control electrode further includes: a first slit extending in the first direction; and
an orthographic projection of the first slit on the base substrate at least partially overlaps with an orthographic projection of the first signal line on the base substrate.

Embodiments of the present disclosure further provide a touch display device, which includes the touch display panel provided by embodiments of the present disclosure.

### BRIEF DESCRIPTION OF FIGURES

FIG. 1A is a first schematic diagrams of a stack of partial film layers provided by embodiments of the present disclosure.

FIG. 1B is a second schematic diagram of a stack of partial film layers provided by embodiments of the present disclosure.

FIG. 1C is a third schematic diagram of a stack of partial film layers provided by embodiments of the present disclosure.

FIG. 1D is a fourth schematic diagram of a stack of partial film layers provided by embodiments of the present disclosure.

FIG. 1E is a fifth schematic diagram of a stack of partial film layers provided by embodiments of the present disclosure.

FIG. 2A is a schematic diagram of a top view of a touch display panel provided by embodiments of the present disclosure.

FIG. 2B is a schematic diagram of the stacking of other film layers except the pixel electrode layer in FIG. 2A.

FIG. 2C is a schematic diagram of a single film layer of the light shielding layer in FIG. 2A.

FIG. 2D is a schematic diagram of a single film layer of the active layer in FIG. 2A.

FIG. 2E is a schematic diagram of a single film layer of the gate line layer in FIG. 2A.

FIG. 2F is a schematic diagram of a single film layer of the interlayer dielectric layer in FIG. 2A.

FIG. 2G is a schematic diagram of a single film layer of the data line layer in FIG. 2A.

FIG. 2H is a schematic diagram of a single film layer of the planarization layer in FIG. 2A.

FIG. 2I is a schematic diagram of a single film layer of the touch control electrode layer in FIG. 2A.

FIG. 2J is a schematic diagram of a single film layer of the passivation layer in FIG. 2A.

FIG. 2K is a schematic diagram of a single film layer of the pixel electrode layer in FIG. 2A.

FIG. 2L is a schematic diagram of a cross-sectional view along the dotted line EF in FIG. 2A.

FIG. 3 is a schematic diagram of a top view of a touch display panel provided by embodiments of the present disclosure under a microscope.

FIG. 4 is a schematic diagram of a touch display panel provided by embodiments of the present disclosure.

FIG. 5A is a schematic diagram of a top view of a touch display panel.

FIG. 5B is an enlarged schematic diagram of the lower left corner of FIG. 5A.

FIG. 6 is a schematic diagram showing a comparison of reflectivity of different types of array substrates.

FIG. 7 is a schematic diagram of a table comparing reflectivity of different types of array substrates.

### DETAILED DESCRIPTION

In order to make the purpose, technical solution and advantages of embodiments of the present disclosure clearer, the technical solutions of embodiments of the present disclosure will be clearly and completely described below in conjunction with the accompanying drawings of embodiments of the present disclosure. Obviously, embodiments described are some embodiments of the present disclosure, not all embodiments. Based on embodiments of the present disclosure described, all other embodiments obtained by a person skilled in the art without creative labor are within the scope of protection of the present disclosure.

Unless otherwise defined, the technical or scientific terms used in this disclosure shall have the ordinary meaning understood by persons with general skill in the field to which this disclosure belongs. The terms “first”, “second” and similar expressions used in this disclosure do not indicate any order, number or importance, but only to distinguish the different components. Words such as “include” or “comprise” mean that the element or object preceding the word includes the element or object listed after the word and its equivalents, and does not exclude other elements or objects. Similar terms such as “coupled” or “connected” are not limited to physical or mechanical connections, but may include electrical connections, whether direct or indirect. “Up”, “Down”, “Left”, “Right”, etc., are only used to indicate the relative positional relationship, and when the absolute position of the object being described changes, the relative positional relationship may also change accordingly.

As used herein, the words “approximately” or “substantially the same” include the stated values and imply an acceptable deviation from the specific values as determined by a person of ordinary skill in the art taking into account the measurements in question and the errors associated with the measurements of the specific quantities (i.e., the limitations of the measurement system). For example, “approximately the same” can mean that the difference from the stated value is within one or more standard deviations, or within the range of ±30%, 20%, 10%, or 5%.

In the drawings, the thickness of layers, films, panels, regions, etc., is enlarged for clarity. In the present disclosure, an exemplary embodiment is described with reference to a cross-sectional diagram that is a schematic diagram of an idealized embodiment. In this way, deviations from the shape of the diagram are expected as a result of, for example, manufacturing techniques and/or tolerances. Therefore, the embodiments described in this article should not be construed as being limited to the specific shape of the region shown herein, but rather as including deviations in the shape caused by, for example, manufacturing. For example, a region that is illustrated or described as flat can typically have rough and/or non-linear characteristics. In addition, the sharp corners shown can be round. Thus, the regions shown in the diagram are inherently schematic, and their shapes do not purport the exact shape of the illustrated regions and are not intended to limit the scope of the claims.

In order to keep the following descriptions of the embodiments of the present disclosure clear and concise, the detailed descriptions of known functions and known parts are omitted.

For the Touch In Cell structure, the touch function is realized by the touch pad (TPM Pad) made of the data line layer, and the TPM Pad exists in each group of pixels, but a large part of the TPM Pad is used as a floating (Dummy) and has no practical effect. For the Dummy TPM Pad, it will directly lead to the following two problems. On the one hand, it will cause display afterimages. In some embodiments, in terms of the reflectivity of the array substrate, the Dummy TPM Pad will cause the reflectivity of the array substrate to increase by about 1%, and then during the photolithography patterning process, it will cause overexposure, affecting the underlying alignment film layer, resulting in uneven alignment film pattern, and further causing afterimage problems when the display is produced. On the other hand, TPM pads can cause adjacent wire spaces to become smaller, and particles to fall between adjacent wires, resulting in an increased risk of metal residue and connecting adjacent signal lines, thereby reducing product yield.

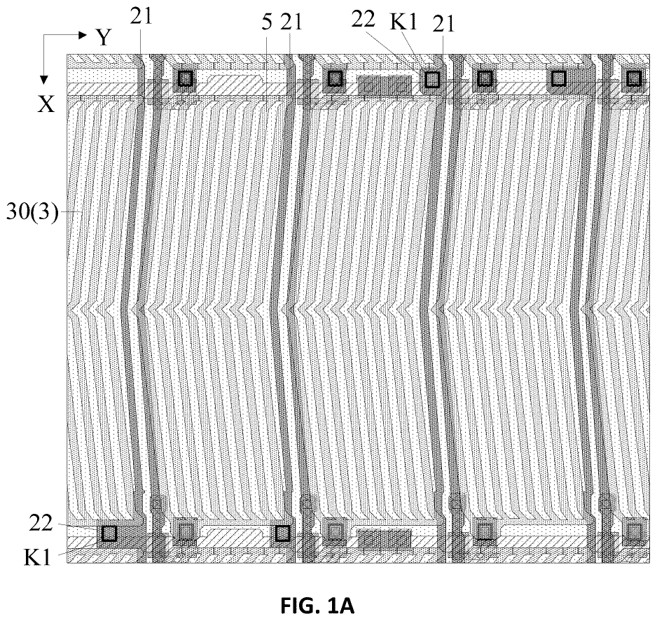

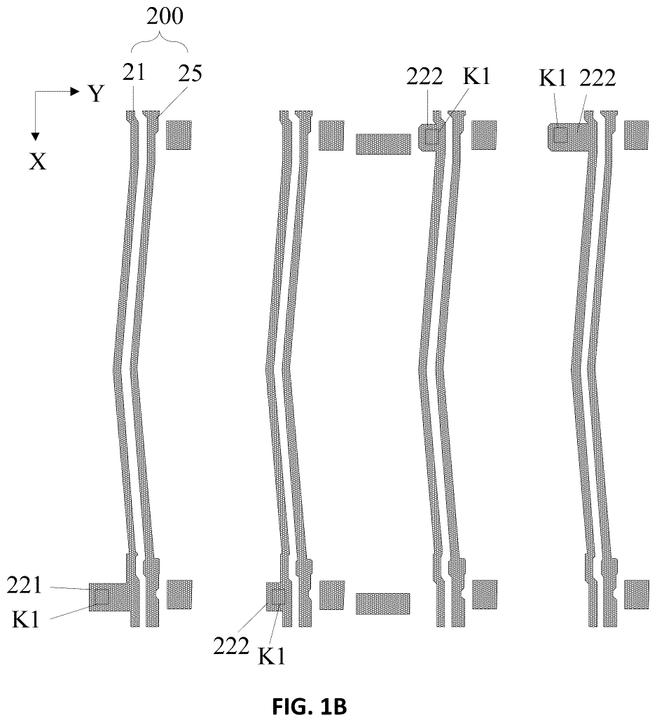

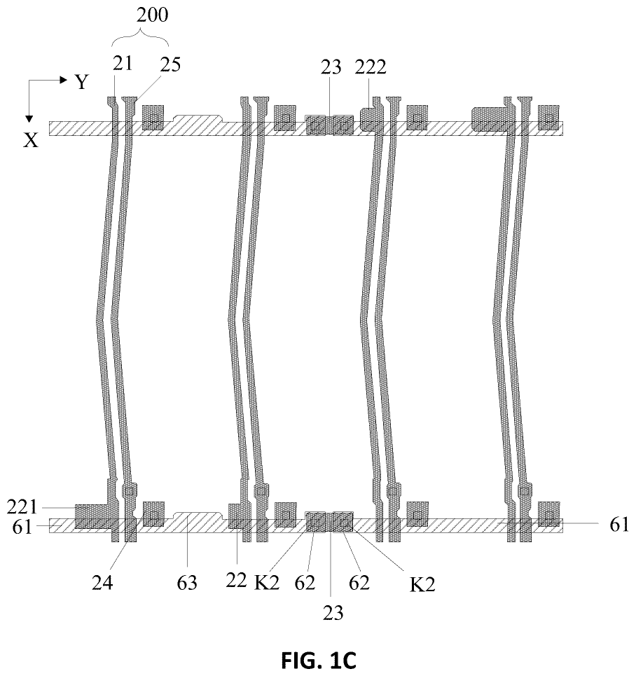

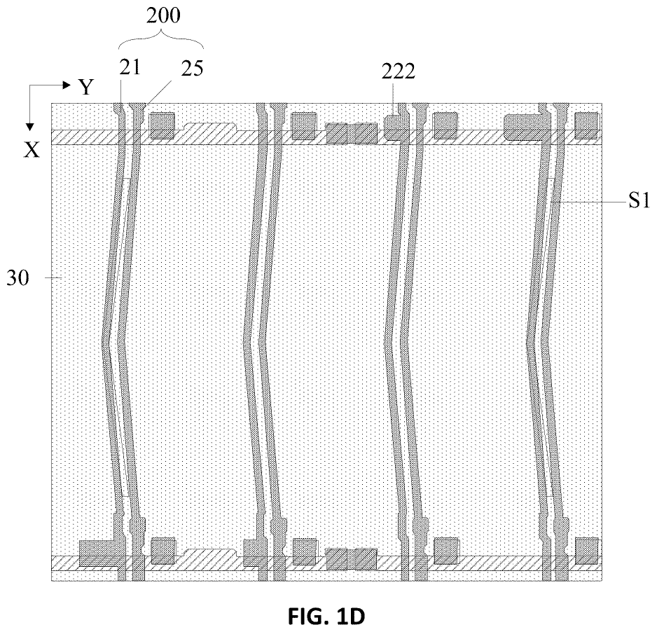

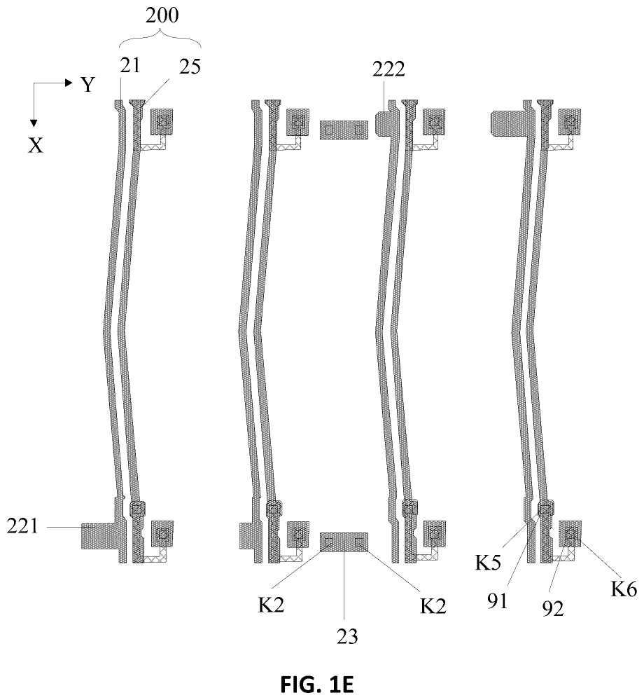

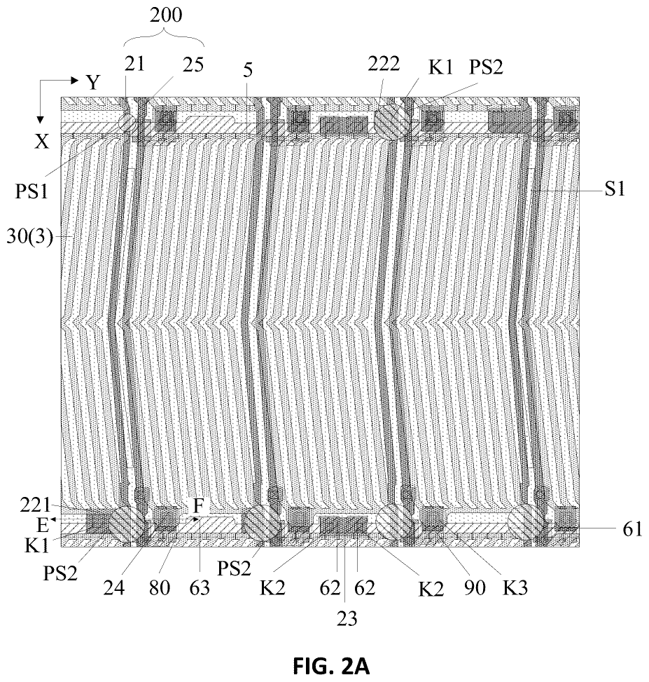

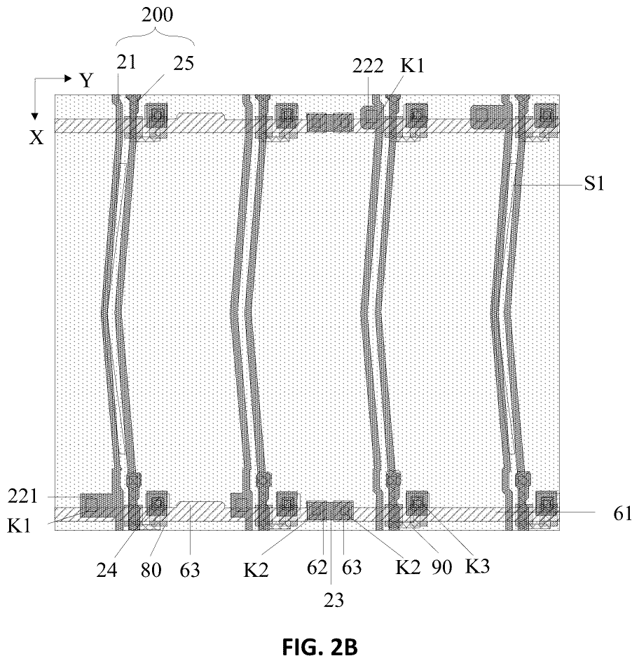

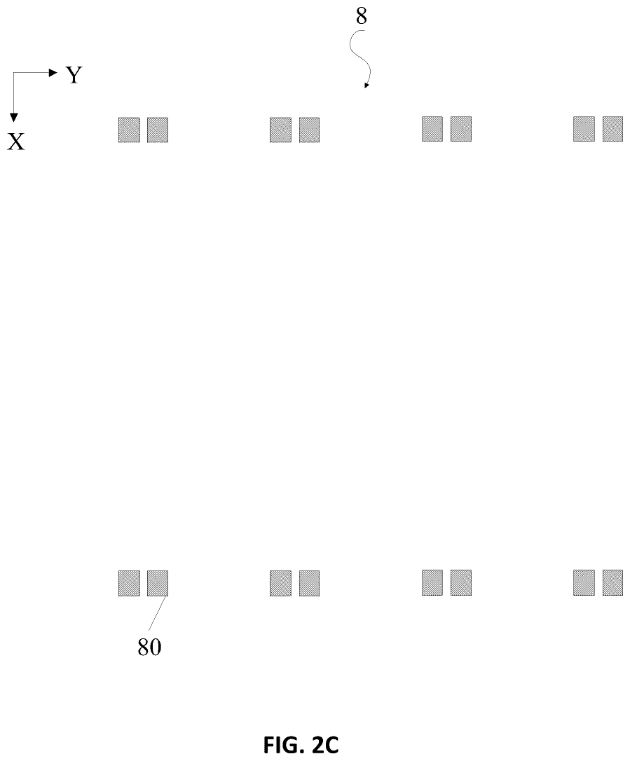

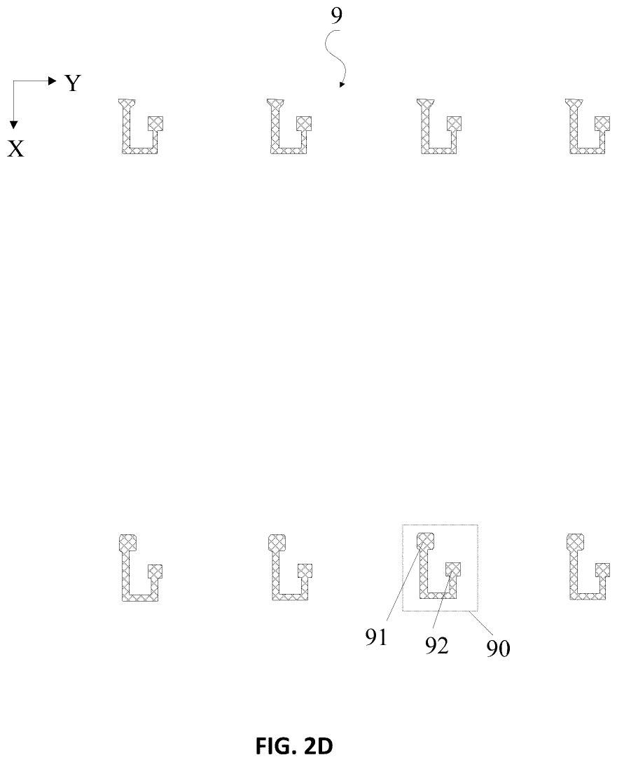

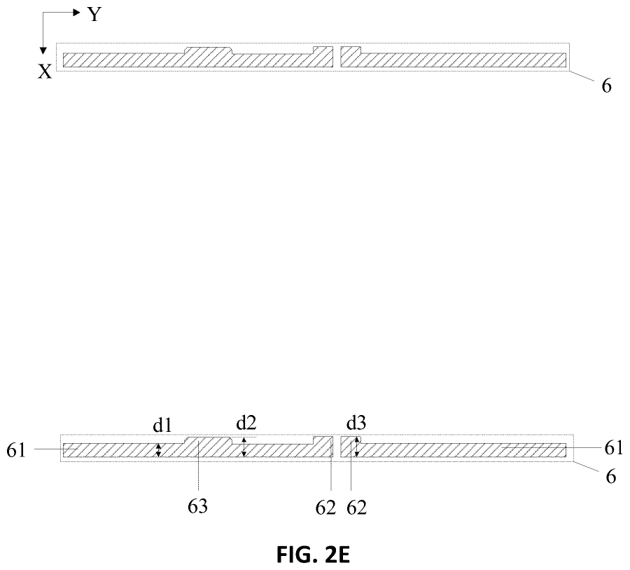

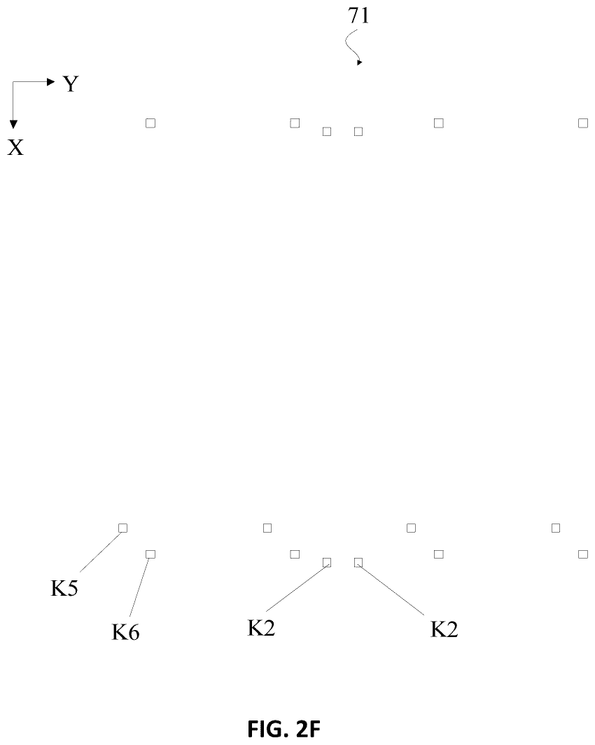

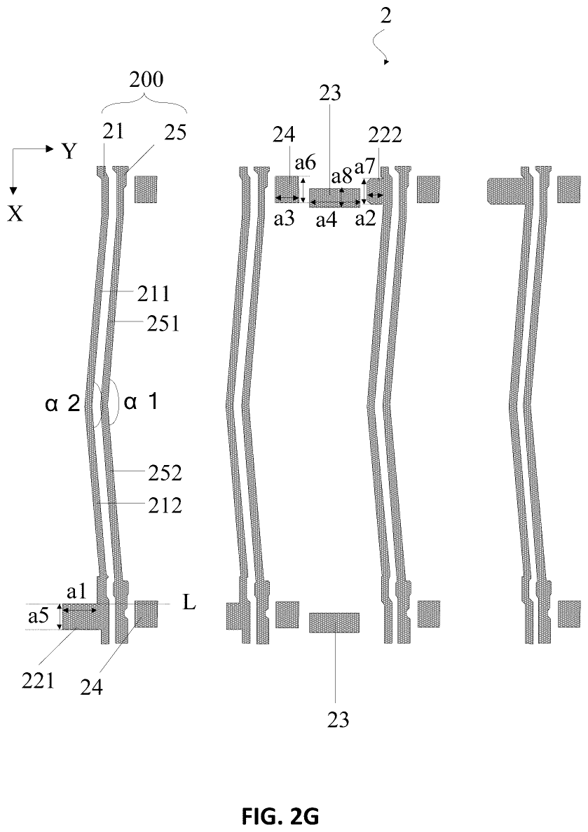

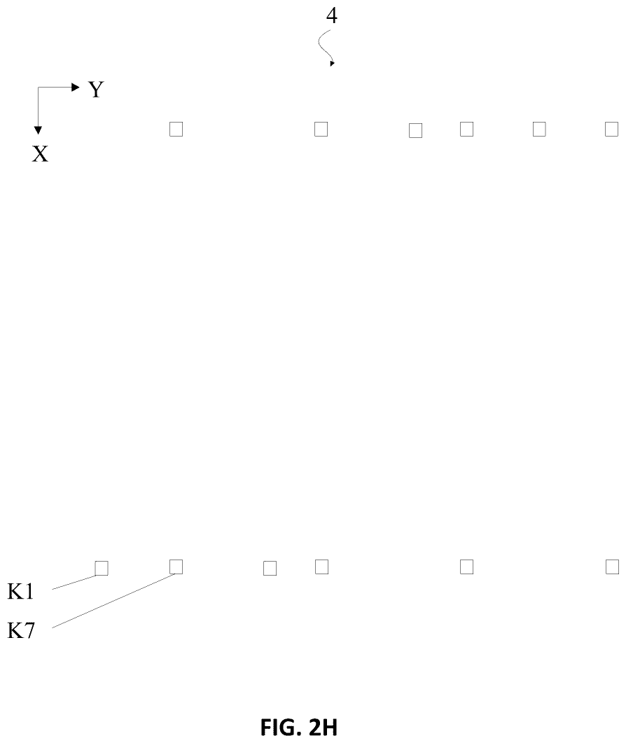

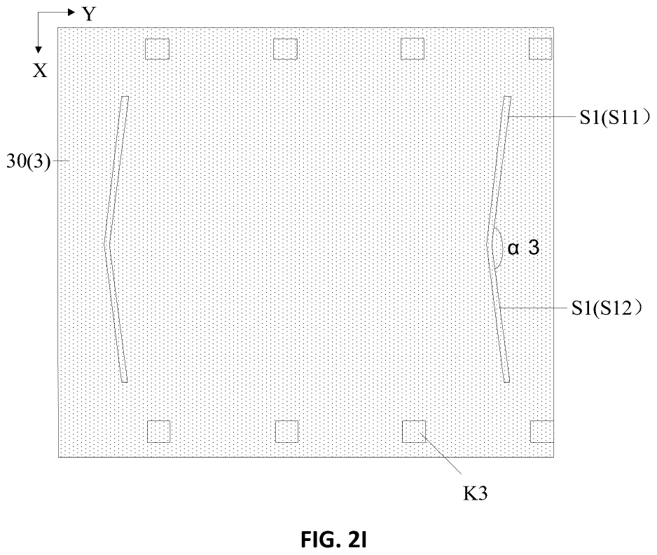

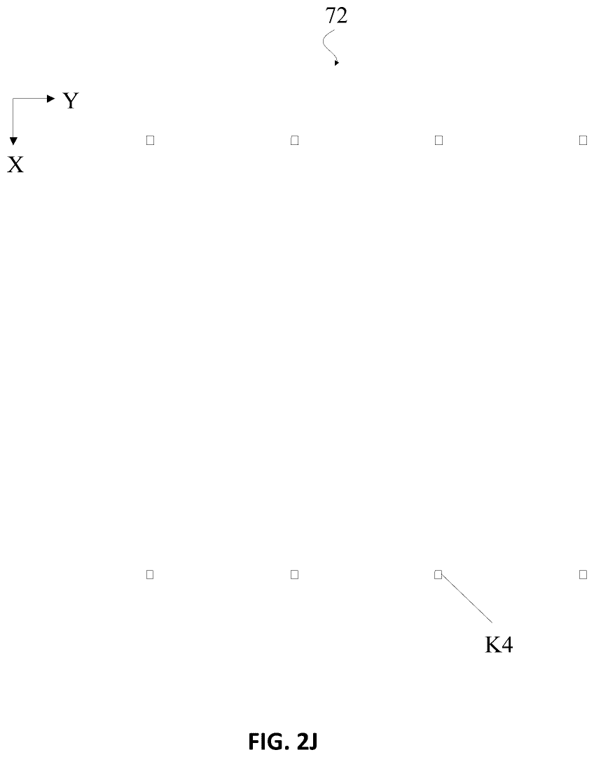

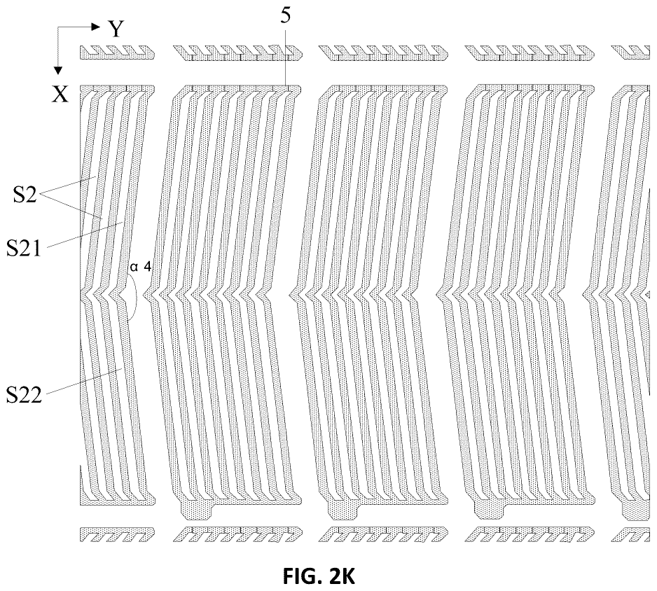

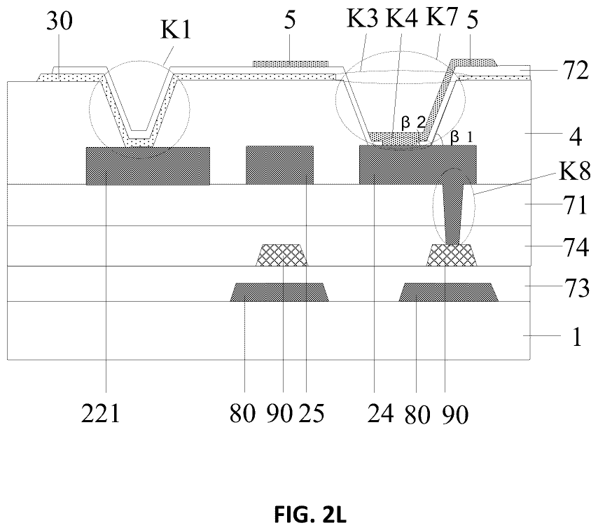

In view of this, referring to FIGS. 1A to 1E, FIGS. 2A to 2K, and FIG. 3, FIG. 1A is a first schematic diagrams of a stack of partial film layers provided by embodiments of the present disclosure. FIG. 1B is a second schematic diagram of a stack of partial film layers provided by embodiments of the present disclosure. FIG. 1C is a third schematic diagram of a stack of partial film layers provided by embodiments of the present disclosure. FIG. 1D is a fourth schematic diagram of a stack of partial film layers provided by embodiments of the present disclosure. FIG. 1E is a fifth schematic diagram of a stack of partial film layers provided by embodiments of the present disclosure. FIG. 2A is a schematic diagram of a top view of a touch display panel provided by embodiments of the present disclosure. FIG. 2B is a schematic diagram of the stacking of other film layers except the pixel electrode layer in FIG. 2A. FIG. 2C is a schematic diagram of a single film layer of the light shielding layer in FIG. 2A. FIG. 2D is a schematic diagram of a single film layer of the active layer in FIG. 2A. FIG. 2E is a schematic diagram of a single film layer of the gate line layer in FIG. 2A. FIG. 2F is a schematic diagram of a single film layer of the interlayer dielectric layer in FIG. 2A. FIG. 2G is a schematic diagram of a single film layer of the data line layer in FIG. 2A. FIG. 2H is a schematic diagram of a single film layer of the planarization layer in FIG. 2A. FIG. 2I is a schematic diagram of a single film layer of the touch control electrode layer in FIG. 2A. FIG. 2J is a schematic diagram of a single film layer of the passivation layer in FIG. 2A. FIG. 2K is a schematic diagram of a single film layer of the pixel electrode layer in FIG. 2A. The present disclosure provides a touch display panel, the touch display panel includes:
a base substrate;
a first electrode layer 2, on a side of the base substrate, where the first electrode layer 2 includes: a plurality of first signal lines 21 extending in a first direction X, and a plurality of electrode portions 22 connected to the plurality of first signal lines 21;
a touch control layer 3, on a same side of the base substrate as the first electrode layer 2, where the touch control layer 3 includes: a plurality of touch control electrodes 30 spaced apart from each other;
a first insulating layer, on a same side of the base substrate as the first electrode layer 2, between the first electrode layer 2 and the touch control layer 3, where the first insulating layer is provided with a plurality of first via holes K1; at least some of the plurality of electrode portions 22 are electrically connected to the touch control electrodes 30 through the first via holes K1;
a plurality of pixel electrodes 5, on the same side of the base substrate as the first electrode layer 2;
where orthographic projections of the plurality of electrode portions 22 on the base substrate are only located at orthographic projections of gaps between some adjacent pixel electrodes 5 of the plurality of pixel electrodes 5 on the base substrate. In some embodiments, the gap between adjacent pixel electrodes 5 can be the gap between two adjacent pixel electrodes 5 in the first direction X. In some embodiments, the orthographic projection of the electrode portion 22 on the base substrate can also overlap with the orthographic projection of the pixel electrode 5 on the base substrate.

In embodiments of the present disclosure, orthographic projections of the plurality of electrode portions 22 on the base substrate are only located at orthographic projections of gaps between some adjacent pixel electrodes 5 of the plurality of pixel electrodes 5 on the base substrate. Compared to the conventional structure, each pixel electrode 5 is equipped with an electrode portion 22 next to it. The electrode portion 22 in embodiments of the present disclosure is only located next to a portion of the pixel electrodes 5, which can improve the problem that excessive electrode portions 22 can cause high reflectivity of the array substrate, affect the exposure of the alignment film, cause uneven patterning of the alignment film layer, and further lead to residual image problems during display. In addition, the electrode portion 22 in embodiments of the present disclosure is only located next to a portion of the pixel electrodes 5, which can further improve the problem that excessive electrode portion 22 can cause a reduction in the space between the first signal line 21 and the data line 22, resulting in metal residue caused by particles falling between the first signal line 21 and the data line 22, leading to a low product yield. Moreover, the cost of the touch display panel will not increase, which means that the touch display panel provided in embodiment of the present disclosure can improve the residual image performance of the touch display panel without increasing costs, while reducing the defect rate of the touch display panel.

It should be noted that in order to clearly illustrate the relationship between the various film layers of the touch panel in FIG. 2B, the pixel electrode 5 is not shown, and embodiments of the present disclosure are not limited to this. In some embodiments, the touch display panel can be provided with the pixel electrodes 5, as shown in FIG. 2A.

In some embodiments, the touch control layer 3 is also reused as a common electrode layer, and signals are loaded in a time-sharing manner to achieve touch and display functions. For example, in the first period, a common signal is loaded to the touch control layer 3 so that the touch control layer 3 acts as a common electrode layer to realize the display function; in the second period, a touch signal is loaded to the touch control layer so that the touch control layer 3 acts as a touch control layer to realize the touch monitoring function.

In some embodiments, all electrode portions 22 are electrically connected to the touch control electrodes 30 through the first via holes K1. That is, in embodiments of the present disclosure, the remaining electrode portions 22 are all effective electrode portions 22 that are conductive with the touch control electrodes 30, and there are no dummy electrode portions 22 that are not loaded with electrical signals, thereby minimizing the adverse effects of the dummy electrode portions 22 that are not loaded with electrical signals on the touch display panel.

In some embodiments, some of the electrode portions 22 are electrically connected to the touch control electrodes 30 through the first via holes K1. That is, in embodiments of the present disclosure, there can also be a small number of dummy electrode portions 22 that are not loaded with electrical signals.

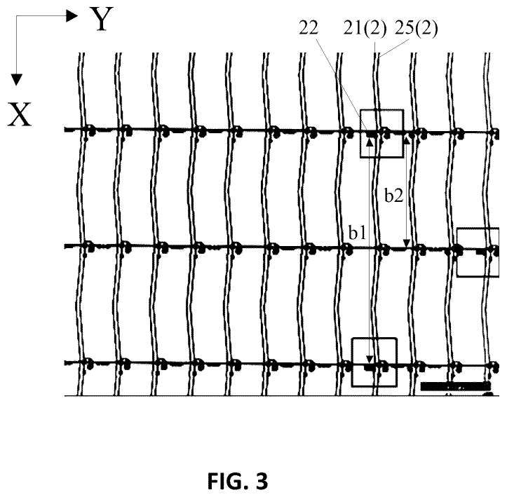

In some embodiments, a minimum distance between orthographic projections of at least some adjacent electrode portions 22 in the first direction X on the base substrate is greater than a length of an orthographic projection of the pixel electrode 5 on the base substrate in the first direction X. For example, as shown in FIG. 3, in the first direction X, the minimum distance b1 between two adjacent electrode portions 22 (the position shown in the box in FIG. 3 is the position of the electrode portion 22) on the base substrate is greater than the length b2 of a pixel electrode 5 on the base substrate in the same direction. In some embodiments, in the first direction X (the column direction), there can be at least one pixel electrode 5 spaced apart with an electrode portion 22.

In some embodiments, the minimum distances between orthographic projections of all adjacent electrode portions 22 on the base substrate in the first direction X can be greater than a length of an orthographic projection of the pixel electrode 5 on the base substrate in the first direction X. That is, the minimum distance between orthographic projections of any two adjacent electrode portions 22 on the base substrate in the first direction X can be greater than the length of an orthographic projection of the pixel electrode 5 on the base substrate in the first direction X.

In some embodiments, a minimum distance between orthographic projections of at least some adjacent electrode portions 22 on the base substrate in a second direction Y is greater than a length of an orthographic projection of the pixel electrode 5 on the base substrate 2 in the second direction Y, and the second direction Y is perpendicular to the first direction X. That is, as shown in FIG. 3, in the second direction Y (the row direction), there can be at least one pixel electrode 5 spaced apart with an electrode portion 22.

In some embodiments, the minimum distances between orthographic projections of all adjacent electrode portions 22 on the base substrate in the second direction Y can be greater than a length of an orthographic projection of the pixel electrode 5 on the base substrate 2 in the second direction Y. That is, the minimum distance between orthographic projections of any two adjacent electrode portions 22 on the base substrate in the second direction Y can be greater than the length of an orthographic projection of the pixel electrode 5 on the base substrate in the second direction Y.

In some embodiments, along at least one of the first direction X and the second direction Y, a minimum distance between orthographic projections of two adjacent electrode portions 22 on the base substrate is greater than a width of orthographic projections of at least two pixel electrodes 5 on the base substrate in the same direction. That is, as shown in FIG. 3, in the first direction X, two adjacent electrode portions 22 can be separated by at least two pixel electrodes 5. For another example, in the second direction Y, two adjacent electrode portions 22 can be separated by at least two pixel electrodes 5.

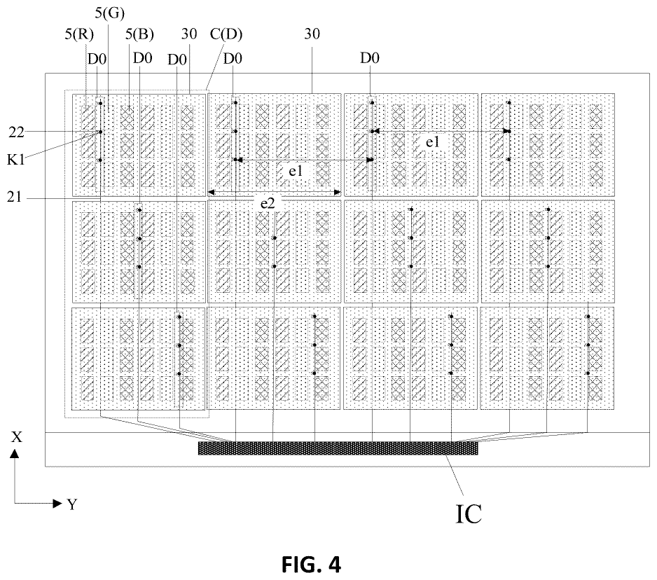

In some embodiments, since the orthographic projection area of the touch control electrode 30 on the base substrate is larger than the orthographic projection area of the pixel electrode 5 on the base substrate, the region where one touch control electrode 30 is located can cover multiple pixel electrodes 5, and the electrode portion 22 is arranged around the pixel electrode 5, and the region where one touch control electrode 30 is located can also be covered by multiple electrode portions 22. In some embodiments, as shown in FIG. 4, the touch control layer 3 includes: a plurality of touch control electrode groups C extending in the first direction X and arranged in the second direction Y; the plurality of electrode portions 22 include: a plurality of electrode portion groups D extending in the first direction X and arranged in the second direction Y. The orthographic projection of the touch control electrode group C on the base substrate at least partially overlaps with the orthographic projection of the electrode portion group D on the base substrate. In some embodiments, the orthographic projection of the touch control electrode group C on the base substrate can cover the orthographic projection of the electrode portion group D on the base substrate. In some embodiments, the touch control electrode group C corresponds to the electrode portion group D one by one, and the plurality of electrode portions 22 in the region covered by the touch control electrode group C can be used as the electrode portion group D.

At least one electrode portion group D among the multiple electrode portion groups D includes: a plurality of sub-electrode portion groups D0 arranged in the first direction X, the sub-electrode portion group D0 including at least one electrode portion 22. The orthographic projection of the touch control electrode 30 on the base substrate at least partially overlaps with the orthographic projection of the sub-electrode portion group D0 on the base substrate. In some embodiments, the orthographic projection of the touch control electrode 30 on the base substrate covers the orthographic projection of the sub-electrode portion group D0 on the base substrate. In some embodiments, the touch control electrode 30 corresponds to the sub-electrode portion group D0 one-to-one, and the multiple electrode portions 22 in the region covered by the touch control electrode 30 can be used as the sub-electrode portion group D0; the sub-electrode portion groups D0 in the same electrode portion group D are staggered. In embodiments of the present disclosure, while removing redundant electrode portions 22 to improve the of the touch display panel and increase the defective rate, different touch control electrodes 30 are electrically connected to different first signal lines 21, so that the first signal lines 21 can provide signals to different touch control electrodes 30, and/or transmit the signals detected by the touch control electrodes 30 to the first signal lines 21, and then transmit them to the control chip IC by the first signal lines 21.

In some embodiments, for the staggered distribution of each sub-electrode portion group D0 in the same electrode group D, the side edge extension lines of the electrode portions 22 in different electrode groups D (for example, the right side edge extension lines of the electrode portions 22 in different electrode groups D in FIG. 4) may not overlap. In some embodiments, as shown in FIG. 4, for the first touch control electrode 30 in the first column from the left, the first touch control electrode 30 from top to bottom can correspond to retaining the electrode portion 22 around the second column of pixel electrodes 5, so as to be electrically connected to the first signal line 21 through the electrode portion 22 around the second column of pixel electrodes 5, and then be connected to the IC, and the remaining electrode portions in the region where the touch control electrode 30 is located are removed. For the second touch control electrode 30 from top to bottom, the electrode portion 22 around the fourth column of pixel electrodes 5 can correspond to retaining the electrode portion 22 around the fourth column of pixel electrodes 5, so as to be electrically connected to the first signal line 21 through the electrode portion 22 around the fourth column of pixel electrodes 5, and then be connected to the IC, and the remaining electrode portions in the region where the touch control electrode 30 is located are removed. For the third touch control electrode 30 from top to bottom, the electrode portion 22 around the sixth column of pixel electrodes 5 can correspond to retaining the electrode portion 22 around the sixth column of pixel electrodes 5, so as to be electrically connected to the first signal line 21 through the electrode portion 22 around the sixth column of pixel electrodes 5, and then be connected to the IC, and the remaining electrode portions in the region where the touch control electrode 30 is located are removed. That is, each touch control electrode 30 selects the electrode portion 22 next to a column of pixel electrodes 5 for connection to the control chip IC; and the rest are removed, and each touch control electrode 30 is independently connected to the control chip IC without affecting each other. Of course, the above is only an example of a connection method between the touch control electrode 30 and the electrode portion 22, and the embodiments of the present disclosure is not limited to this, and other distribution methods can also be used. For example, for the first touch electrode 30 from top to bottom, the electrode portions 22 around the second column of pixel electrodes 5 are retained. For the second touch electrode 30 from top to bottom, the electrode portions 22 around the third column of pixel electrodes 5 are retained. For the third touch electrode 30 from top to bottom, the electrode portions 22 around the fourth column of pixel electrodes 5 are retained. For a column of touch control electrodes 30, the electrode portions 5 around different columns of pixel electrodes 5 are selected from top to bottom at equal intervals to be connected to the touch control electrodes 30, which can make the layout of the electrode portions 22 and the first signal lines more concise and beautiful and match the design of the conventional control chip IC.

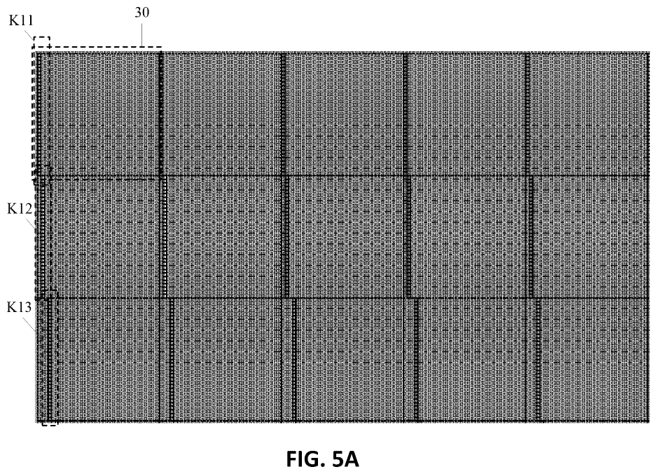

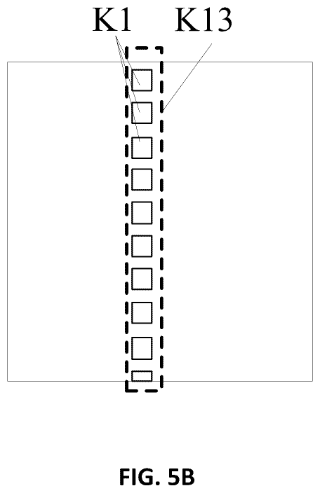

In some embodiments, in combination with FIG. 5A and FIG. 5B, FIG. 5A is a schematic diagram of a top view of a touch display panel. FIG. 5B is an enlarged schematic diagram of the lower left corner of FIG. 5A. FIG. 5A shows 3 rows and 5 columns of touch control electrodes 30, each touch control electrode 30 covers a plurality of pixel electrodes 5. In some embodiments, for a column of touch control electrodes 30, the via hole groups opened by different touch control electrodes 30 can be staggered in sequence. For example, for the first column of touch control electrodes 30 on the left, the second via hole group K12 opened corresponding to the second touch control electrode 30 from top to bottom can be offset to the right relative to the first via hole group K11 opened corresponding to the first touch control electrode 30 from top to bottom. The third via hole group K13 opened corresponding to the third touch control electrode 30 from top to bottom can be further offset to the right relative to the second via hole group K12 opened corresponding to the second touch control electrode 30 from top to bottom . . . , and the via hole groups are offset in sequence to realize the electrical connection of different touch control electrodes 30 in the same column with the corresponding electrode portion 22. In some embodiments, the first via hole group K11, the second via hole group K12, and the third via hole group K13 can each include a plurality of first via holes K1, and each first via hole K1 correspondingly exposes one electrode portion 22.

It should be noted that FIG. 4 is a schematic illustration of an example in which a touch display panel has 3 rows and 4 columns of touch control electrodes 30, and 3 rows and 6 columns of pixel electrodes 5 in the region where each touch control electrode 30 is located. In some embodiments, the touch display panel can include more rows and columns of touch control electrodes 30, and each touch control electrode 30 can have more rows and columns of pixel electrodes 5 in the region where the touch control electrode 30 is located, and the embodiments of the present disclosure are not limited to this. Similarly, FIG. 4 is only a schematic illustration of the outer contour of the pixel electrode 5 as a rectangle. In some embodiments, the pixel electrode 5 can also be other shapes, and can also include slits, and the embodiments of the present disclosure are not limited to this. In addition, FIG. 5B only shows a plurality of first via holes K1, but does not show other film layer structures, in order to clearly illustrate the distribution of the third via hole group K13. However, the embodiments of the present disclosure are not limited thereto.

In some embodiments, the region covered by one touch control electrode 30 can only include the electrode portions 22 in the sub-electrode portion group D0, and the electrode portions 22 in the region outside the sub-electrode portion group D0 cannot be provided.

In some embodiments, as shown in FIG. 4, the electrode portions 22 in the same sub-electrode portion group D0 are located in the same column. In some embodiments, each electrode portion 22 in the same sub-electrode portion group D0 is located at a gap between two adjacent columns of pixel electrodes 5. For example, as shown in FIG. 4, the first sub-electrode portion group D0 on the left side from top to bottom is located at the gap between the first column of pixel electrodes 5 and the second column of pixel electrodes 5.

In some embodiments, as shown in FIG. 4, different sub-electrode portion groups D0 in the same electrode portion group D are located in gaps between pixel electrodes 5 in different columns. For example, as shown in FIG. 4, the first sub-electrode portion group D0 from top to bottom on the left side is located in the gap between the first column of pixel electrodes 5 and the second column of pixel electrodes 5; for another example, the second sub-electrode portion group D0 from top to bottom on the left side is located in the gap between the third column of pixel electrodes 5 and the fourth column of pixel electrodes 5.

In some embodiments, as shown in FIG. 4, the electrode portions 22 in the same sub-electrode portion group D0 are electrically connected to the same first signal line 21.

In some embodiments, as shown in FIG. 4, the electrode portions 22 located in the same region where the touch control electrode 30 is located are located in the same column. In some embodiments, the electrode portions 22 located in the same region where the touch control electrode 30 is located are located in the gap between two adjacent columns of pixel electrodes 5. For example, as shown in FIG. 4, the first sub-electrode portion group D0 from the left in the region where the first row of touch control electrodes 30 is located is located in the gap between the first column of pixel electrodes 5 and the second column of pixel electrodes 5.

In some embodiments, as shown in FIG. 4, the electrode portions 22 located in the same region where the touch control electrode 30 is located are electrically connected to the same first signal line 21. The region covered by the touch control electrode 30 cannot include the electrode portion 22 which is not electrically connected to the first signal line 21.

In some embodiments, as shown in FIG. 4, the distance e1 between two adjacent sub-electrode portion groups D0 in the second direction Y is substantially equal to the width e2 of the touch control electrode 30 in the second direction Y. That is, for the second column of touch control electrodes 20 from the left, the electrode portion 22 selected to be connected to the first signal line 21 can correspond to the position of the electrode portion 22 selected to be connected to the first signal line 21 by the first column of touch control electrodes 20 from the left. That is, the first touch control electrode 20 from top to bottom in the first column of touch control electrodes 20 from the left is connected to the first signal line 21 through the electrode portions 22 around the second column of pixel electrodes 5. For the first touch control electrode 20 from top to bottom in the second column of touch control electrodes 20 from the left, the electrode portions 22 around the second column of pixel electrodes 5 in the region covered by the touch control electrode 20 can also be selected to be connected to the corresponding first signal line 21. In this way, it has the advantages of being regular, simple and beautiful and matching conventional control chip IC.

In some embodiments, as shown in FIG. 4, the distance e1 between two adjacent sub-electrode portion groups D0 can be the distance between the sides of two adjacent electrode portions 22 in the same row electrically connected to the first signal line 21 (for example, the right side of the electrode portion 22 connected to the first signal line 21 in FIG. 2G).

In some embodiments, for the touch control electrodes 30 in the same row, between the two sub-electrode portion groups D0 in the coverage region corresponding to adjacent touch control electrodes 30, there may not be any other electrode portions 22 provided. That is, as shown in FIG. 4, in the region covered by the first row of touch control electrodes 30, there is no other electrode portion 22 between the first sub-electrode portion group D0 from the left and the second sub-electrode portion group D0 from the left.

In some embodiments, as shown in FIG. 4, in the second direction Y, a distance e1 between one pair of two adjacent sub-electrode portion groups D0 is substantially equal to a distance e1 between another pair of two adjacent sub-electrode portion groups D0. For example, in the region covered by the first row of touch control electrodes 30, the distance between the second sub-electrode portion group D0 and the third sub-electrode portion group D0 is substantially equal to the distance between the third sub-electrode portion group D0 and the fourth sub-electrode portion group D0. In some embodiments, in a direction perpendicular to the first direction X, the distance e1 between any adjacent sub-electrode portion groups D0 can be substantially equal.

In some embodiments, referring to FIG. 2A, the electrode portion 22 includes: a first-type electrode portion 221; the touch display panel further includes: an array substrate and an opposite substrate arranged opposite to each other; the opposite substrate is provided with a first spacer PS1 on a side facing the array substrate, and the first spacer PS1 includes a first surface facing the array substrate (specifically, the first spacer PS1 can have a top surface and a bottom surface, where the bottom surface can contact the opposite substrate, and the top surface can face to the array substrate, and the first surface can be the top surface of the first spacer PS); at least part of an orthographic projection of the first-type electrode portion 221 on the base substrate has an overlapping area with an orthographic projection of the first surface on the base substrate. In another embodiment, a part of the orthographic projection of the first-type electrode portion 221 on the base substrate cannot have an overlapping region with the orthographic projection of the first surface on the base substrate, as shown in FIG. 2A.

It should be noted that the first spacer PS1 shown in FIG. 2A can be an orthographic projection of the first surface of the first spacer PS1 on the array substrate.

In some embodiments, referring to FIG. 1B, the orthographic projection of the first via hole K1 on the base substrate does not overlap with the orthographic projection of the first surface on the base substrate 1. In embodiments the present disclosure, the orthographic projection of the first via hole K1 on the base substrate does not overlap with the orthographic projection of the first surface on the base substrate 1, so that the first spacer PS1 is not disposed in the region where the first via hole K1 is located, which may affect the conduction effect between the electrode portion 22 and the touch control electrode 30, and when the first spacer PS1 is in the region where the first via hole K1 is located, the contact surface is uneven and easy to move, and the first spacer PS1 cannot provide a stable support.

In some embodiments, as shown in FIG. 2A, the opposite substrate can further be provided with a second spacer PS2. In some embodiments, the height of the first spacer PS1 in a direction perpendicular to the base substrate 1 can be greater than the height of the second spacer PS2 in a direction perpendicular to the base substrate 1, that is, the first spacer PS1 can be a main spacer, and the second spacer PS2 can be a secondary spacer. In some embodiments, the first surface of the first spacer PS1 can be in contact with the array substrate; and the second spacer PS2 cannot be in contact with the array substrate. In embodiments of the present disclosure, for the column where the first spacer PS1 is located, the length of the electrode portion 22 retained in the column in the second direction Y can be made longer (as the first-type electrode portion 221), and for the column where the first spacer PS is not provided, the electrode portion 22 can be made shorter (as the second-type electrode portion 222), so as to avoid the first spacer PS1 being in contact with the array substrate when the first spacer PS1 is placed at the position of the electrode portion 22 of the column. If the first spacer PS1 is in contact with the first via hole K1, it will affect the support effect.

In some embodiments, a second spacer PS2 can also be provided for the column where the first spacer PS is located. Since the second spacer PS2 can contact the array substrate only when the display panel is pressed, and can be in a non-contact state with the array substrate when not pressed, the orthographic projection of the second spacer PS2 on the base substrate 1 can overlap with the orthographic projection of the first via hole K1, or cannot overlap with the orthographic projection of the first via hole K1.

In some embodiments, as shown in FIG. 1B, the electrode portion 22 further includes: a second-type electrode portion 222; an orthographic projection of the second-type electrode portion 222 on the base substrate and an orthographic projection of the first surface on the base substrate do not overlap each other.

In some embodiments, in combination with FIG. 1B and FIG. 2G, the electrode portion 22 includes: a first-type electrode portion 221 and a second-type electrode portion 222; the length a1 of the first-type electrode portion 221 in the second direction Y is greater than the length a2 of the second-type electrode portion 222 in the second direction Y. In embodiments of the present disclosure, for the electrode portion 22 in the column where the first spacer PS1 is located, the length of the electrode portion 22 in the first direction X can be made longer, serving as the first-type electrode portion 221; and for the electrode portion 22 in the column where the first spacer PS1 is not located, the length of the electrode portion 22 can be made shorter, serving as the second-type electrode portion 222; the adverse effects of the electrode portion 22 on the touch display panel can be minimized.

In some embodiments, in combination with FIGS. 1C, 2E and 2F, the touch display panel further includes: a plurality of gate lines 6 extending in the second direction Y; at least one gate line 6 among the plurality of gate lines 6 includes: a plurality of first sub-gate line portions 61 arranged in sequence along the second direction Y; adjacent first sub-gate line portions 61 are disconnected; the touch display panel further includes: a transfer portion 23 arranged on the side of the electrode portion 22 away from the first signal line 21; the orthographic projection of the transfer portion 23 on the base substrate has an overlapping region with the orthographic projection of the first sub-gate line portion 61 on the base substrate. The touch display panel further includes: a second insulating layer 71 between the first electrode layer 2 and the gate line 6, the second insulating layer 71 is provided with a second via hole K2; the transfer portion 23 is electrically connected to the first sub-gate line portion 61 through the second via hole K2. In embodiments of the present disclosure, the gate line 6 is divided into a plurality of first sub-gate line portions 61 which are disconnected from each other, so as to avoid the problem that static electricity is easily generated when the gate line 6 is too long, causing the gate line 6 to be easily burned.

In some embodiments, in combination with FIGS. 1C, 2E and 2F, the gate line 6 further includes: a connection end 62 connected to the end of the first sub-gate line portion 61; a width d3 of the connection end 62 in the first direction X is greater than a width d1 of the first sub-gate line portion 61 in the first direction X; one end of the transfer portion 23 is connected to the connection end 62 of one first sub-gate line portion 61 through a second via K2, and the other end of the transfer portion 23 is connected to the connection end 62 of another first sub-gate line portion 61 through another second via hole K2, so that adjacent first sub-gate line portions 61 are connected through the transfer portion 23. In embodiments of the present disclosure, when the electrode portion 22 is only provided around a part of the pixel electrodes 5, there can be more wiring space, and the position of the transfer portion 23 can be flexibly set as needed. In some embodiments, in order to avoid the problem that the gate line 6 is long and prone to static electricity, the transfer portion 23 is provided to perform a jumper design through the layer where the data line 25 is located. When the transfer portion 23 is located between the first electrode 24 of the transistor and the electrode portion 22, the space between the first electrode 24 of the transistor, the electrode portion 22 and the intermediate transfer portion 23 will become smaller, and the size of the electrode portion 22 will be compressed accordingly. At this time, the distance (Margin) between the outer edge of the first via hole K1 and the outer edge of the electrode portion 22 becomes smaller, and the risk of metal residue (Remain)/broken wire (Open) increases accordingly. In addition, the first via hole K1 will further be closer to the overlapping position of the layer where the gate line 6 and the data line 25 are located, increasing the risk of the spacer falling off the first via hole K1, resulting in poor display. For example, in a 200 PPI product, the space between the first electrode 24 of the transistor and the strip-shaped transfer portion 23 is 3 μm, which is the lower limit of the current design rules. When the PPI increases, if it is still necessary to ensure that it is above 3 μm, the space needs to compress the size of the transfer portion 23; the overlap margin between the first via hole K1 and the electrode portion 22 is correspondingly reduced, increasing the problem of hole exposure/overlap offset, resulting in dark spots/flickering (Crack) or poor display of the first via hole K1 due to the spacer falling off. In embodiments of the present disclosure, when the electrode portion 22 is only provided around a portion of the pixel electrodes 5, the wiring distribution space of the transfer portion 23 is larger, the wiring is more flexible, and can be actually adjusted according to the different designs of different models of touch display panels, and the overall yield risk is greatly reduced.

In some embodiments, in combination with FIG. 2E, the gate line 6 further includes: a second sub-gate line portion 63 connected to the first sub-gate line portion 61; the width d2 of the second sub-gate line portion 63 in the first direction X is greater than the width d1 of the first sub-gate line portion 61 in the first direction X; the width d2 of the second sub-gate line portion 63 in the first direction X is approximately equal to the width d3 of the connection end 62 in the first direction X. In embodiments of the present disclosure, the gate line 6 further includes a second sub-gate line portion 63 with a wider line width, which can reduce the resistance of the gate line 6 and improve the problem that the gate line 6 has a large line resistance that affects signal transmission.

In some embodiments, as shown in FIG. 2E, the width d1 of the first sub-gate line portion 61 in the first direction X can be 1 μm to 10 μm. In some embodiments, the width d1 of the first sub-gate line portion 61 in the first direction X can be 2 μm to 8 μm. In some embodiments, the width d1 of the first sub-gate line portion 61 in the first direction X can be 2 μm, 3 μm, 3.5 μm, 4 μm, 5 μm, 6 μm, 7 μm, or 8 μm.

In some embodiments, as shown in FIG. 2E, a width d2 of the second sub-gate line portion 63 in the first direction X can be substantially equal to a width d3 of the connection end 62 in the first direction X.

In some embodiments, as shown in FIG. 2E, the width d3 of the connection end 62 in the first direction X can be 1 μm to 10 μm. In some embodiments, the width d3 of the connection end 62 in the first direction X can be 3 μm to 8 μm. In some embodiments, the width d3 of the connection end 62 in the first direction X can be 3 μm, 4 μm, 5 μm, 5.9 μm, 6 μm, 7 μm, or 8 μm.

In some embodiments, as shown in FIG. 1C, the orthographic projection of the second sub-gate line portion 63 on the base substrate does not overlap with the orthographic projection of the electrode portion 22 (including the first-type electrode portion 21 and the second-type electrode portion 22) on the base substrate. In this way, it is possible to avoid a large overlap capacitance between the second sub-gate line portion 63 and the electrode portion 22, which would affect the signal transmission of the gate line 6.

In some embodiments, in combination with what is shown in FIG. 2G, the touch display panel further includes: a first electrode 24 of a transistor; the electrode portion 22 includes a second-type electrode portion 222; and between at least some adjacent first signal lines 21, an orthographic projection of the transfer portion 23 on the base substrate is located between an orthographic projection of the first electrode 24 of the transistor on the base substrate and an orthographic projection of the second-type electrode portion 222 on the base substrate.

In some embodiments, as shown in FIG. 2G, the electrode portion 22 includes a first-type electrode portion 221; a length a2 of the second-type electrode portion 222 in the second direction Y is smaller than a length a3 of the first electrode 24 of the transistor in the second direction Y. In some embodiments, the length a2 of the second-type electrode portion 222 in the second direction Y can also be substantially equal to the length a3 of the first electrode 24 of the transistor in the second direction Y. In some embodiments, the length a2 of the second-type electrode portion 222 in the second direction Y can also be greater than the length a3 of the first electrode 24 of the transistor in the second direction Y.

In some embodiments, as shown in FIG. 2G, a length a3 of the first electrode 24 of the transistor in the second direction Y is smaller than a length a4 of the transfer portion 23 in the first direction X. In some embodiments, the length a3 of the first electrode 24 of the transistor in the second direction Y can also be greater than the length a4 of the transfer portion 23 in the first direction X. In some embodiments, the length a3 of the first electrode 24 of the transistor in the second direction Y can also be equal to the length a4 of the transfer portion 23 in the first direction X.

In some embodiments, as shown in FIG. 2G, a length a1 of the first-type electrode portion 221 in the second direction Y is greater than a length a3 of the first electrode 24 of the transistor in the second direction Y, and a length a1 of the first-type electrode portion 221 in the second direction Y is less than a length a4 of the transfer portion 23 in the second direction Y. In some embodiments, the length a1 of the first-type electrode portion 221 in the second direction Y can also be greater than or equal to the length a3 of the first electrode 24 of the transistor in the second direction Y. In some embodiments, the length a1 of the first-type electrode portion 221 in the second direction Y can also be greater than or equal to the length a4 of the transfer portion 23 in the second direction Y.

In some embodiments, referring to FIG. 2G, the length a1 of the first-type electrode portion 221 in the second direction Y can be 10 μm to 20 μm. In some embodiments, the length a1 of the first-type electrode portion 221 in the second direction Y can be 12 μm to 18 μm. In some embodiments, the length a1 of the first-type electrode portion 221 in the second direction Y can be 12 μm, 14 μm, 14.9 μm, 15 μm, 16 μm, 17 μm, or 18 μm.

In some embodiments, as shown in FIG. 2G, the length a2 of the second-type electrode portion 222 in the second direction Y can be 1 μm to 10 μm. In some embodiments, the length a2 of the second-type electrode portion 222 in the second direction Y can be 5 μm to 8 μm. In some embodiments, the length a2 of the second-type electrode portion 222 in the second direction Y can be 5 μm, 6 μm, 6.1 μm, 6.5 μm, 7 μm, or 8 μm.

In some embodiments, as shown in FIG. 2G, the length a3 of the first electrode 24 of the transistor in the second direction Y can be 5 μm to 15 μm. In some embodiments, the length a3 of the first electrode 24 of the transistor in the second direction Y can be 8 μm to 13 μm. In some embodiments, the length a3 of the first electrode 24 of the transistor in the second direction Y can be 8 μm, 9 μm, 10 μm, 10.5 μm, 11 μm, or 12 μm.

In some embodiments, as shown in FIG. 2G, the length a4 of the transfer portion 23 in the second direction Y can be 15 μm to 25 μm. In some embodiments, the length a4 of the transfer portion 23 in the second direction Y can be 18 μm to 23 μm. In some embodiments, the length a4 of the transfer portion 23 in the second direction Y can be 18 μm, 19 μm, 19.5 μm, 20 μm, 21 μm, 22 μm, or 23 μm.

In some embodiments, referring to FIG. 2G, the length a5 of the first-type electrode portion 221 in the first direction X can be substantially equal to the length a6 of the second-type electrode portion 222 in the first direction X. In some embodiments, referring to FIG. 2G, the length a6 of the second-type electrode portion 222 in the first direction X can be substantially equal to the length a7 of the first electrode 24 of the transistor in the first direction X. In some embodiments, referring to FIG. 2G, the length a6 of the second-type electrode portion 222 in the first direction X can be greater than the length a8 of the transfer portion 23 in the first direction X.

In some embodiments, as shown in FIG. 2G, the length a8 of the transfer portion 23 in the first direction X can be 5 μm to 15 μm. In some embodiments, the length a8 of the transfer portion 23 in the first direction X can be 6 μm to 10 μm. In some embodiments, the length a8 of the transfer portion 23 in the first direction X can be 6 μm, 7 μm, 7.2 μm, 7.5 μm, 8 μm, 9 μm, or 10 μm.

In some embodiments, referring to FIG. 2G, the length a1 of the first-type electrode portion 221 in the second direction Y can be greater than the length of the first via hole K1 in the second direction Y. In some embodiments, referring to FIG. 2G, the length a2 of the second-type electrode portion 222 in the second direction Y can be greater than the length of the first via hole K1 in the second direction Y.

In some embodiments, the distance between the centers of adjacent pixel electrodes 5 in the first direction X can be 5 μm to 15 μm. In some embodiments, the distance between the centers of adjacent pixel electrodes 5 in the first direction X can be 5 μm, 6 μm, 7 μm, 8 μm, 8.5 μm, 9 μm, 10 μm, 11 μm, 12 μm, 13 μm, 14 μm or 15 μm.

In some embodiments, the distance between the centers of adjacent pixel electrodes 5 in the second direction Y can be 5 μm to 15 μm. In some embodiments, the distance between the centers of adjacent pixel electrodes 5 in the second direction Y can be 5 μm, 6 μm, 7 μm, 8 μm, 8.5 μm, 9 μm, 9.8 μm, 10 μm, 11 μm, 12 μm, 13 μm, 14 μm or 15 μm.

In some embodiments, the distance between the centers of adjacent pixel electrodes 5 in the second direction Y can be greater than the distance between the centers of adjacent pixel electrodes 5 in the first direction X.

In some embodiments, the sum of the length a1 of the first-type electrode portion 221 in the second direction Y and the length a3 of the first electrode of the transistor 24 in the second direction Y can be less than one third of the length of the pixel unit in the second direction Y. In some embodiments, the sum of the length a2 of the second-type electrode portion 222 in the second direction Y, the length a3 of the first electrode of the transistor 24 in the second direction Y, and the length a4 of the transfer portion 23 in the second direction Y can be less than one third of the length of the pixel unit in the second direction Y. In some embodiments, the pixel unit can include three sub-pixels of red, green, and blue.

In some embodiments, the length of the pixel unit in the second direction Y can be 30 μm to 200 μm. In some embodiments, the length of the pixel unit in the second direction Y can be 30 μm, 40 μm, 50 μm, 60 μm, 70 μm, 80 μm, 90 μm, 100 μm, 110 μm, 120 μm, 130 μm, 140 μm, 150 μm, 160 μm, 165 μm, 167.1 μm, 170 μm, 180 μm, 190 μm or 200 μm.

In some embodiments, referring to FIG. 2G, the touch display panel further includes: a plurality of data lines 25 extending in a first direction Y, and a first electrode 24 of a transistor electrically connected to the pixel electrode 5; one first signal line 21 and one data line 25 form a signal wiring group 200. In the same signal wiring group 200, the electrode portion 22 is electrically connected to a side of the first signal line 21 away from the data line 25, and the first electrode 24 of the transistor is located on a side of the data line 25 away from the first signal line 21.

In some embodiments, as shown in FIG. 2G, the data line 25 in the region between two adjacent gate lines 6 can include: a first data portion 251 and a second data line portion 252 arranged in the first direction X, the extension line of the first data portion 251 and the extension line of the second data portion 252 do not overlap. In some embodiments, a first angle α1 formed by the first data line portion 251 and the second data portion 252 can be an obtuse angle. In some embodiments, the first signal line 21 in the region between two adjacent gate lines 6 can include a first signal portion 211 and a second signal portion 212 arranged in sequence in the first direction X, the extension line of the first signal portion 211 and the extension line of the second signal portion 212 do not overlap. In some embodiments, a second angle α2 formed by the first signal portion 211 and the second signal portion 212 can be an obtuse angle. In some embodiments, the first data portion 251 and the first signal portion 211 can be parallel, the second data portion 252 and the second signal portion 212 can be parallel, and the first angle α1 and the second angle α2 can be equal.

In some embodiments, as shown in FIG. 2G, the orthographic projection of the outer edge extension line L of the electrode portion 22 parallel to the second direction Y on the base substrate overlaps with the orthographic projection of the first electrode 24 of the transistor on the base substrate. That is, the electrode portion 22 and the first electrode 24 of the transistor can be arranged substantially in the same row.

In some embodiments, as shown in FIG. 2G, the first signal line 21 and the data line 25 are arranged in the same layer. In this way, the first signal line 21 can be formed while the data line 25 is formed, so as to simplify the manufacturing process of the touch display panel.

In some embodiments, the touch control layer 3 is located between the first electrode layer 2 and the layer where the pixel electrode 5 is located; as shown in FIG. 21, the touch control electrode 30 includes: a third via hole K3; the pixel electrode 5 is connected to the first electrode 24 of the transistor through the third via hole K3.

In some embodiments, as shown in combination with FIG. 1D and FIG. 21, the touch control electrode 30 further includes a first slit S1 extending in the first direction X, and an orthographic projection of the first slit S1 on the base substrate at least partially overlaps with an orthographic projection of the first signal line 21 on the base substrate. In some embodiments, as shown in FIG. 21, the first slit S1 can include a first sub-slit S11 and a second sub-slit S12 arranged in the first direction X. In some embodiments, the extension line of the first sub-slit S11 and the extension line of the second sub-slit S12 cannot overlap with each other. In some embodiments, the third angle α3 formed by the first sub-slit S11 and the second sub-slit S12 can be an obtuse angle. In some embodiments, the third angle α3 can be substantially equal to the first angle α1.

In some embodiments, as shown in FIG. 2K, the pixel electrode 5 can have a plurality of second slits S2; the second slit S2 can include: a third sub-slit portion S21 and a fourth sub-slit portion S22 arranged in sequence along the first direction X, where the extension line of the third sub-slit portion S21 and the extension line of the fourth sub-slit portion S22 cannot overlap. In some embodiments, a fourth angle α4 formed by the third sub-slit portion S21 and the fourth sub-slit portion S22 can be an obtuse angle. In some embodiments, the fourth angle α4 can be substantially equal to the first angle α1. In some embodiments, the first slit S1 can have a similar shape to the second slit S2.

In some embodiments, the first insulating layer 4 can be a planarization layer. The first electrode layer 2 can be the layer where the data line 25 is located; the first electrode layer 2 can be arranged on the side of the gate line 6 facing away from the base substrate; the touch control layer 3 can be arranged on the side of the first electrode layer 2 facing away from the base substrate, and the pixel electrode layer 5 can be arranged on the side of the touch control layer 3 facing away from the base substrate; an active layer 9 can be arranged between the base substrate and the layer where the gate line 6 is located; a light shielding layer 8 can be arranged between the base substrate and the active layer 9, and a second insulating layer 71 can be arranged between the gate line 6 and the layer where the data line 25 is located; a passivation layer 72 can be arranged between the touch control layer 3 and the layer where the pixel electrode 5 is located. As shown in FIGS. 2A to 2L, FIG. 2L is a cross-sectional schematic diagram along the dotted line EF in FIG. 2A. The touch display panel can be sequentially provided with: a buffer layer 73, a light shielding layer 8 (including a plurality of light shielding patterns 80), an active layer 9 (including a plurality of active patterns 90), a gate insulating layer 74, a gate line 6, a second insulating layer 71 (which can be an interlayer dielectric layer), a first electrode layer 2 (a layer where the data line 25, the electrode portion 22, and the first electrode 24 of the transistor are located), a first insulating layer 4 (which can also be a planarization layer), a touch control layer 3, and a passivation layer 72.

In some embodiments, as shown in FIG. 2L, the display panel can further include: an eighth via hole K8 penetrating through the second insulating layer 71 and the gate insulating layer 74. The first electrode 24 of the transistor is in contact with the active pattern 90 through the eighth via hole K8.

In some embodiments, as shown in FIG. 2H and FIG. 2L, the first insulating layer 4 can further have a plurality of seventh via holes K7, so that the pixel electrode 5 is connected to the first electrode 24 of the transistor through the third via hole K3, the fourth via hole K4, and the seventh via hole K7.

In some embodiments, in combination with FIG. 2L, the orthographic projection of the seventh via hole K7 on the base substrate 1 can have an overlapping region with the orthographic projection of the eighth via hole K8 on the base substrate 1. In some embodiments, the orthographic projection of the seventh via hole K7 on the base substrate 1 cannot have an overlapping region with the orthographic projection of the eighth via hole K8 on the base substrate 1. In some embodiments, in combination with FIG. 2L, the orthographic projection of the third via hole K3 on the base substrate 1 can have an overlapping region with the orthographic projection of the eighth via hole K8 on the base substrate 1. In some embodiments, the orthographic projection of the third via hole K3 on the base substrate 1 cannot have an overlapping region with the orthographic projection of the eighth via hole K8 on the base substrate 1. In some embodiments, in combination with FIG. 2L, the orthographic projection of the fourth via hole K4 on the base substrate 1 can have an overlapping region with the orthographic projection of the eighth via hole K8 on the base substrate 1. In some embodiments, the orthographic projection of the fourth via hole K4 on the base substrate 1 cannot have an overlapping region with the orthographic projection of the eighth via hole K8 on the base substrate 1.

In some embodiments, in combination with FIG. 2L, the slope angle β1 formed by the first insulating layer 4 at the seventh via hole K7 can be in the range of 30° to 80°. In some embodiments, the slope angle β1 formed by the first insulating layer 4 at the seventh via hole K7 can be in the range of 40° to 70°. In some embodiments, the slope angle β1 formed by the first insulating layer 4 at the seventh via hole K7 can be in the range of 50° to 65°. In some embodiments, the slope angle β1 formed by the first insulating layer 4 at the seventh via hole K7 can be 50°, 51°, 52°, 53°, 54°, 55°, 56°, 57°, 58°, 59°, 60°, 61°, 62°, 63°, 64°, or 65°.

In some embodiments, in combination with FIG. 2L, the slope angle β2 formed by the passivation layer 72 at the fourth via hole K4 can range from 80° to 110°. In some embodiments, the slope angle β2 formed by the passivation layer 72 at the fourth via hole K4 can range from 85° to 100°. In some embodiments, the slope angle β2 formed by the passivation layer 72 at the fourth via hole K4 can be 85°, 86°, 87°, 88°, 89°, 90°, 91°, 92°, 93°, 94°, or 95°.

In some embodiments, the second insulating layer 71 can be an interlayer dielectric layer. As shown in FIG. 2F, the second insulating layer 71 can also include: a fifth via hole K5, and a sixth via hole K6); the active layer 9 can include a plurality of active patterns 90, and the active pattern 90 can include a source region 91 and a drain region 92. The source region 91 can be connected to the data line 25 through the fifth via K5, and the drain region 92 can be connected to the first electrode 24 of the transistor through the sixth via K6 (as shown in FIG. 1E); the light-shielding layer 8 can have a plurality of light-shielding patterns 80, and the light-shielding pattern 80 can shield at least part of the active pattern 90 of the transistor to prevent the influence of external light on the active pattern. The passivation layer 72 can include a plurality of fourth via holes K4, so that the pixel electrode 5 is connected to the first electrode 24 of the transistor through the third via holes K3 and the fourth via holes K4.

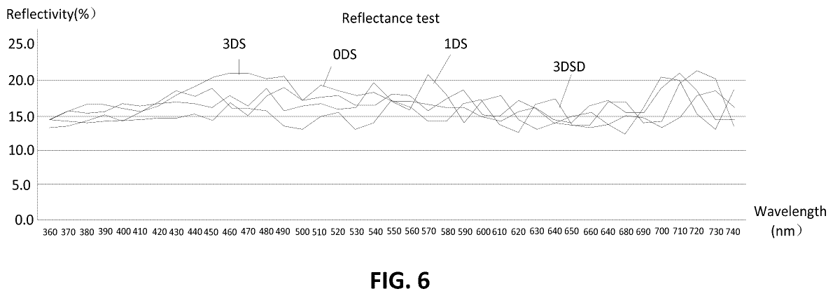

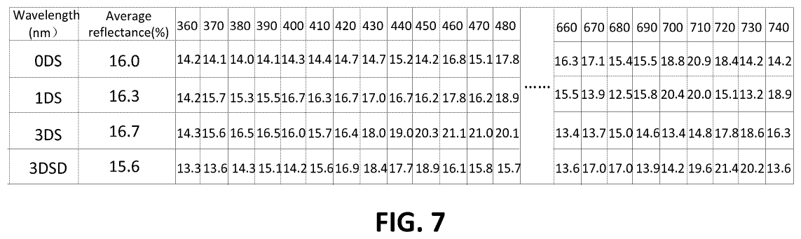

In some embodiments, FIGS. 6 and 7 show the reflectivity of array substrates with similar PPI and different structures, where the number of data lines is different and the Dummy TPM Pad is exist or not. FIG. 6 includes: different reflectivity line graphs corresponding to 0Dual Source structure array substrate 0DS, 1Dual Source structure array substrate 1DS, 3Dual Source structure array substrate 3DS, and 3Dual Source structure array substrate 3DSD without Dummy TPM Pad. FIG. 7 includes: reflectivity values of 0Dual Source structure array substrate 0DS, 1Dual Source structure array substrate 1DS, 3Dual Source structure array substrate 3DS, and 3Dual Source structure array substrate 3DSD without Dummy TPM Pad at different exposure wavelengths, as well as the average reflectivity (Ave). According to FIGS. 6 and 7, it can be clearly seen that, under similar PPI, the more electrode portions 22 (TPM Pad) there are (that is, the number of electrode portions 22 of 0Dual Source structure array substrate 0DS is less than the number of electrode portions 22 of 1Dual Source structure array substrate 1DS; the number of electrode portions 22 of 1Dual Source structure array substrate 1DS is less than the number of electrode portions 22 of 3Dual Source structure array substrate 3DS; the number of electrode portions 22 of 3Dual Source removed Dummy TPM Pad structure array substrate 3DSD is less than the number of electrode portions 22 of 3Dual Source structure array substrate 3DS), the higher the reflectivity, the reflectivity can be reduced by about 1% by removing the Dummy Pad.

In some embodiments, the dummy TPM pads are removed in a periodic arrangement to the greatest extent possible, so as to improve the problem of false detection during the automatic optical inspection (AOI) of the array substrate. In some embodiments, the Dummy Pad can be removed to the greatest extent possible by periodic arrangement in the following ways.
1. Get the distributed TPM Pad.
2. In order to improve the efficiency of drawing and editing AOI inspection methods (recipes), the Dummy TPM Pad can be removed periodically.
3. Find the position of the electrode portion (TPM Pad) according to the touch control electrode, find the minimum period of the electrode portion (TPM Pad) distribution by column/row, and then arrange the array horizontally according to the minimum period.
4. For the vertically staggered arrangement of the touch display panel models, find the minimum period by column.
5. According to the overall distribution evaluation, after the minimum longitudinal period is removed, it can ensure that the dummy pad is removed to the maximum extent without affecting the drawing and detection efficiency.

In summary, for periodic removal of Dummy Pad or manual maximum removal, the choice should be based on the actual situation of the model, comprehensive Dummy Pad removal rate, AOI inspection, drawing cost, and improvement effect.

Based on the same inventive concept, embodiments of the present disclosure further provide a touch display device, including the above touch display panel provided by embodiments of the present disclosure. The implementation of the touch display device can refer to the above-mentioned embodiments of the touch display panel, and the repeated parts will not be repeated.

In the embodiments of the present disclosure, the touch display device can be: a mobile phone, a tablet computer, a television, a monitor, a laptop computer, a digital photo frame, a navigator, or any other product or component with a display function. Other essential components of the display device should be understood by those skilled in the art and will not be described in detail herein and should not be construed as limiting the present disclosure.

Although the preferred embodiments of the present disclosure have been described, those skilled in the art will be able to make additional changes and modifications to these embodiments once the basic inventive concepts are apparent. Therefore, it is intended that the appended claims be construed to include the preferred embodiments and all changes and modifications that fall within the scope of the disclosure.

Evidently those skilled in the art can make various modifications and variations to the present disclosure without departing from the spirit and scope of the present disclosure. Thus the present disclosure is also intended to encompass these modifications and variations therein as long as these modifications and variations to the present disclosure come into the scope of the claims of the present disclosure and their equivalents.

1.-29. (canceled)

30. A touch display panel, comprising:
a base substrate;
a first electrode layer, on a side of the base substrate, wherein the first electrode layer comprises: a plurality of first signal lines extending in a first direction, and a plurality of electrode portions connected to the plurality of first signal lines;
a touch control layer, on the side of the base substrate as the first electrode layer, wherein the touch control layer comprises: a plurality of touch control electrodes spaced apart from each other;
a first insulating layer, between the first electrode layer and the touch control layer, wherein the first insulating layer is provided with a plurality of first via holes; at least some of the plurality of electrode portions are electrically connected to the touch control electrodes through the first via holes;
a plurality of pixel electrodes, on the same side of the base substrate as the first electrode layer;
wherein orthographic projections of the plurality of electrode portions on the base substrate are only located at orthographic projections of gaps between some adjacent pixel electrodes of the plurality of pixel electrodes on the base substrate.

31. The touch display panel according to claim 30, wherein all of the electrode portions are electrically connected to the touch control electrodes through the first via holes.

32. The touch display panel according to claim 31, wherein a minimum distance between orthographic projections of at least some adjacent electrode portions on the base substrate in the first direction is greater than a length of an orthographic projection of the pixel electrode on the base substrate in the first direction.

33. The touch display panel according to claim 30, wherein a minimum distance between orthographic projections of at least some adjacent electrode portions on the base substrate in a second direction is greater than a length of an orthographic projection of the pixel electrode on the base substrate in the second direction, and the second direction is perpendicular to the first direction.

34. The touch display panel according to claim 33, wherein the touch control layer comprises: a plurality of touch control electrode groups extending in the first direction and arranged in the second direction;
the plurality of electrode portions comprise: a plurality of electrode portion groups extending in the first direction and arranged in the second direction, wherein an orthographic projection of the touch control electrode group on the base substrate at least partially overlaps with an orthographic projection of the electrode portion group on the base substrate;
at least one electrode portion group of the plurality of electrode portion groups comprises: a plurality of sub-electrode portion groups arranged in the first direction, wherein the sub-electrode portion group comprises: at least one electrode portion of the plurality of electrode portions; an orthographic projection of the touch control electrode on the base substrate at least partially overlaps with an orthographic projection of the sub-electrode portion group on the base substrate;
the sub-electrode portion groups in a same electrode portion group are arranged in a staggered manner.

35. The touch display panel according to claim 34, wherein each of the electrode portions in a same sub-electrode portion group is located in a gap between adjacent columns of pixel electrodes.

36. The touch display panel according to claim 34, wherein each of the electrode portions in a same sub-electrode portion group is electrically connected to a same first signal line.

37. The touch display panel according to claim 34, wherein each of the electrode portions in a same region where the touch control electrode is located is located in a gap between adjacent columns of pixel electrodes; or
wherein each of the electrode portions in a same region where the touch control electrode is located is electrically connected to a same first signal line.

38. The touch display panel according to claim 34, wherein a spacing between two adjacent sub-electrode portion groups in the second direction is substantially equal to a width of the touch control electrode in the second direction; or
wherein a spacing between one pair of two adjacent sub-electrode portion groups in the second direction is substantially equal to a spacing between another pair of two adjacent sub-electrode portion groups in the second direction.

39. The touch display panel according to claim 33, wherein the electrode portion comprises: a first-type electrode portion;
the touch display panel comprises: an array substrate and an opposite substrate arranged opposite to each other;
wherein the opposite substrate is provided with a first spacer on a side facing the array substrate; the first spacer comprises a first surface facing the array substrate;
an orthographic projection of at least some of the first-type electrode portions on the base substrate has an overlapping region with an orthographic projection of the first surface on the base substrate.

40. The touch display panel according to claim 39, wherein an orthographic projection of the first via hole on the base substrate and the orthographic projection of the first surface on the base substrate do not overlap with each other; or
wherein the electrode portion further comprises: a second-type electrode portion; an orthographic projection of the second-type electrode portion on the base substrate and the orthographic projection of the first surface on the base substrate do not overlap with each other.

41. The touch display panel according to claim 33, wherein the electrode portion comprises a first-type electrode portion and a second-type electrode portion; and
a length of the first-type electrode portion in the second direction is greater than a length of the second-type electrode portion in the second direction.

42. The touch display panel according to claim 30, wherein:
the touch display panel further comprises a plurality of gate lines extending in a second direction; wherein at least one gate line of the plurality of gate lines comprises: a plurality of first sub-gate line portions sequentially arranged in the second direction; and adjacent first sub-gate line portions are disconnected;
the touch display panel further comprises a transfer portion arranged at a side of the electrode portion away from the first signal line; wherein an orthographic projection of the transfer portion on the base substrate and an orthographic projection of the first sub-gate line portion on the base substrate have an overlapping region;
the touch display panel further comprises a second insulating layer between the first electrode layer and the gate line, wherein the second insulating layer is provided with a second via hole; and the transfer portion is electrically connected to the first sub-gate line portion through the second via hole.

43. The touch display panel according to claim 42, wherein the gate line further comprises: a connection end connected to an end of the first sub-gate line portion; a width of the connection end in the first direction is greater than a width of the first sub-gate line portion in the first direction;
one end of the transfer portion is connected to a connection end of one first sub-gate line portion through one second via hole, and the other end of the transfer portion is connected to a connection end of another first sub-gate line portion through another second via hole, so that adjacent first sub-gate line portions are connected through the transfer portion.

44. The touch display panel according to claim 43, wherein the gate line further comprises: a second sub-gate line portion connected to the first sub-gate line portion;
a width of the second sub-gate line portion in the first direction is greater than a width of the first sub-gate line portion in the first direction; and
the width of the second sub-gate line portion in the first direction is substantially equal to a width of the connection end in the first direction;
wherein an orthographic projection of the second sub-gate line portion on the base substrate does not overlap with an orthographic projection of the electrode portion on the base substrate.

45. The touch display panel according to claim 42, further comprising: a first electrode of a transistor; wherein the electrode portion comprises a second-type electrode portion;
in a gap between at least some adjacent first signal lines, the orthographic projection of the transfer portion on the base substrate is located between an orthographic projection of the first electrode of the transistor on the base substrate and an orthographic projection of the second-type electrode portion on the base substrate.

46. The touch display panel according to claim 45, wherein a length of the second-type electrode portion in the second direction is smaller than a length of the first electrode of the transistor in the second direction; or
wherein a length of the first electrode of the transistor in the second direction is smaller than a length of the transfer portion in the first direction; or
wherein the electrode portion comprises: a first-type electrode portion; a length of the first-type electrode portion in the second direction is greater than a length of the first electrode of the transistor in the second direction; and the length of the first-type electrode portion in the second direction is less than a length of the transfer portion in the second direction.

47. The touch display panel according to claim 30, further comprising: a plurality of data lines extending in the first direction and a first electrode of a transistor electrically connected to the pixel electrode;
one first signal line and one data line form a signal wiring group;
in a same signal wiring group, the electrode portion is electrically connected to a side of the first signal line away from the data line, and the first electrode of the transistor is arranged on a side of the data line away from the first signal line.

48. The touch display panel according to claim 47, wherein an orthographic projection of an extension line of an outer edge of the electrode portion parallel to the second direction on the base substrate overlaps with an orthographic projection of the first electrode of the transistor on the base substrate; or
wherein the first signal line and the data line are arranged in a same layer; or
wherein the touch control layer is arranged between the first electrode layer and a layer where the pixel electrode is located; the touch control electrode comprises: a third via hole; wherein the pixel electrode is connected to the first electrode of the transistor through the third via hole; wherein the touch control electrode further comprises: a first slit extending in the first direction; and an orthographic projection of the first slit on the base substrate at least partially overlaps with an orthographic projection of the first signal line on the base substrate.

49. A touch display device, comprising the touch display panel according to claim 30.
